(19) United States
(12) Patent Application Publication
(10) Pub. No.: US 2002/0006030 A1
(43) Pub. Date: Jan. 17, 2002

(54) Universal media module

(76) Inventors: Daniel R. Evanson, Prior Lake, MN (US); Darren Allen Groth, Fridley, MN (US); Glendon D. Kappel, Eagan, MN (US); Donald Wayne Selg, Mendota Heights, MN (US); Gerard Nicholas Weisensel, Savage, MN (US)

Correspondence Address: RIDER, BENNETT, EGAN & ARUNDEL, 333 SOUTH SEVENTH STREET, SUITE 2000, MINNEAPOLIS, MN, 55402, US

(21) Appl. No.: 09/827,077

(22) Filed: Apr. 5, 2001

Related U.S. Application Data
(60) Provisional application No. 60/195,039, filed on Apr. 6, 2000.

(51) Int. Cl. H05K 7/16; H05K 5/00

(52) U.S. Cl. 361/724; 361/725; 361/726; 361/727

(57) ABSTRACT

A universal media module for use with a data storage library system containing at least one storage array for holding at least one universal media module. The universal media module is removable from the storage array. The universal media module is capable of containing a variety of media cartridges of various sizes, and the media cartridges may vary in size in at least one dimension. The universal media module has a housing having a top wall, bottom wall, side walls, rear wall, and an open front; a mechanism for removably attaching the housing to the data storage library system; and at least one media storage slot formed by supporting members engaging the side walls of the housing and extending along the side walls from the open front to the rear wall. Optionally, each media storage slot can have: an adaptive part selector apparatus to contact the media cartridge and being deflectable along at least one dimension to securely hold a media cartridge within the media storage slot; a media cartridge identification apparatus to engage the identification feature of a media cartridge and to identify the media cartridge type to the operator; and an automatic media cartridge retention apparatus to disengage the media cartridge's retention feature when the media storage module is attached to the data storage library system and to engage the media cartridge's retention feature when the media storage module is removed from the data storage library system.

### BACKGROUND OF THE INVENTION

This application is a continuation of a provisional application, Serial No. 60/195039, filed Apr. 6, 2000.

The present application relates to removable media magazines for data storage libraries, and in particular to removable media magazines that are adaptable for a variety of media sizes.

Data storage library systems are electromechanical devices which contain multiple drives and pieces of data storage media to accommodate installations requiring mass data storage. Media cartridges are stored in columnar arrays to facilitate picking and placing from the storage slots into designated readable/writable drive subsystems. The storage arrays are configured to accommodate specific types and quantities of media. In addition, some end-users require the ability to quickly remove a specific number of pieces of media for archival or off-site usage. By designing a universal module with a specific predetermined footprint, one has the ability to use a single component to serve multiple media requirements. In addition, this same component can be used to fulfill the requirement of removable media magazines.

The progression of storage media has offered challenges dealing with differences in the sizes and features of the media cartridges. Protecting investments of current storage media designs while adapting and planning for future storage media technology solutions offers a potential of mixed media within a library. Certain manufacturers' data storage libraries (HP, Breece Hill Technologies) advertise DLT and LTO technology within the same library, including field retrofitability of DLT to LTO.

Current media cartridges have a variety of physical dimensions. A universal magazine should be designed to accommodate any number of different cartridge dimensions within its confines.

In addition, media cartridges need to be snugly secured within the slots of the magazine. Media cartridges have differing physical features (such as slots and tabs) which enhance the ability of the magazine to securely hold the media in place. The universal magazine should accommodate these varying physical features.

Moreover, these varying physical features may be used as a key to signal the data storage library and the human operator as to which types of media cartridges are stored in which slots within which modules.

The present invention is intended for use in automated, data storage library applications with removable cartridges.

Because of the number of cartridge magazines that are used in automated, data storage library applications is relatively high, a low cost production means of producing the apparatus is a competitive advantage.

Media cartridges must be held securely in place while the universal media module is moved between library storage columns or among library systems or between a library system and an external storage location. However, after the universal media module is securely inserted into a library storage column, the media cartridges must be removable from the universal media module in order to allow proper function of the robotics.

Previous magazines incorporating this capability had complex multiple part designs that required separate processing and assembly operations to produce them. In addition, most of these magazines required manual operation of the media release mechanism, if any, to engage/disengage the retention feature. These previous magazines utilized separate parts for automatic cartridge disengagement because of the need to disengage the retention feature for extended periods within the library cartridge store walls at elevated temperatures. Because this feature was not a positive engagement to the cartridge, but was a detenting engagement, it required relatively high forces to engage the cartridge during the relocation process to prevent it from being dislodged. An integrally molded feature on these magazines would have been subjected to a relatively high stress to deflect it during the disengagement with the store walls, producing long term permanent deformation potentially rendering the feature inoperable. For this reason, earlier designs used separate parts that used materials that could withstand the prolonged exposure to the high stress and elevated temperatures and still remain functional.

PCT Publication WO 00/25311, dated May 4, 2000 and U.S. Pat. No. 5,927,834, disclose a receiver and magazine assembly for a storage library system with a locking member and actuating member to hold the locking member between locked and unlocked positions with respect to each cartridge for automatically locking and unlocking the cartridge in each magazine cell as the magazine is longitudinally moved with respect to the receiver.

The present invention also relates to an adaptive part selector to allow guiding of various sizes of media into and out of the universal media module. The problem being addressed is that of providing a universal media module to be utilized with various types of media without intervention by the operator.

To pick and place media in a data storage library one needs to carefully constrain the objects of consideration. This requirement in the past has led manufacturers to have dedicated slots for each size of media being used. In order to reduce overall manufacturing costs and to offer a beneficial feature, this invention has been implemented for Ultrium™ LTO™ and DLT Tape™ cartridges. However, the invention has general applicability for any media type and any cartridge type.

There is a need for an adaptive part selector in a universal media module that allows several media types to be transported without the need for alternate universal media module versions.

### SUMMARY OF THE INVENTION

By giving the media module a predetermined size that corresponds to a fixed number of storage slots for specific media types, a universal footprint may be established that allows for a generic storage tower chassis. This strategy allows for a single chassis structure that may be used for any number of different media types. For example, a module may contain 10 pieces of Magneto Optical media. The same module size will also accommodate 13 pieces of DVD-RAM media. A single library chassis can therefore be configured for any media type.

There are a number of other features of the present invention that present objects and advantages over the prior art. For example, most optical disc libraries have storage slots constructed of independent side rails or moldings to comprise the storage towers. This arrangement typically requires additional structure to tie the walls together to provide a consistent slot width for the media. By integrating both sides of the module into a single molding, the width of the slots is controlled within the single component. A number of magnetic tape libraries presently utilize tape cartridge modules (HP, ADIC, Storagetek, Exabyte, etc.).

Furthermore, the universal media module may contain physical features (for example, rectangular cutouts) that will work in conjunction with sensors mounted within the media transport assembly (MTA) to allow for automatic calibration of the library alignment offsets.

The module also contains integrated spring detent fingers, which are used to retain media within the storage slots.

An additional object and advantage of the universal media module is related to the requirement of having removable magazines full of media. The design of the module is such that it may be rigidly mounted within the chassis of the library by easily snapping in, but may also be fitted with its own enclosure and handle to be used as a removable means of storing media.

An additional object and advantage of the present invention is that it may have a recessed area molded into the module to allow for the application of a label that is used to identify slot numbers. This is an important feature when used in a library containing many hundreds of pieces of media.

An additional object and advantage of the present invention is that it may contain storage slots that will adapt to the physical storage features of several types of media by means of a cartridge identification feature. The storage slots may be configured to be either neutral as to media type or specific for a specific media type. Each slot can be established as an individual set or may be comprised as a unit pack of multiple slots and then assembled in a cabinet for automated or shelved for storage.

An additional object and advantage of the present invention is that the storage slot cartridge identification feature may signal the human operator and the data storage library as to the type of media stored in the slot.

An additional object and advantage of the present invention is that the storage slots may have an integral automatic retention feature that retains each of the cartridges in the storage slot during installation to the library storage columns or during loading or unloading new or archived cartridges. When the universal media module is fully inserted into the library storage column, the automatic retention feature is automatically disengaged, allowing media to be picked from the universal media module. The present invention does not require separate parts or their assembly to provide this capability.

An additional object and advantage of the present invention is that the cartridge retention feature may be integrally molded with the universal media module, thus providing low cost of manufacture.

An additional object and advantage of the present invention is that the cartridge retention feature is based on the plastic material apparent modulus to minimize the stress during the disengagement to prevent this feature from becoming inoperable. The direct means to minimize the stress utilizes a relatively long, narrow deflection beam and a positive engagement retention feature, separate from a detenting feature, that allows the cartridge to be removed and inserted by the robotics.

An additional object and advantage of the present invention is that includes an adaptive part selector feature.

As the object enters the universal media module it is controlled by the pulling (or pushing) force of the picker. The guides within the universal media module have a certain amount of taper to facilitate receipt of the object being handled.

The object is supported on the bottom by a fixed or compliant surface. It may also be guided on the sides by fixed or compliant surfaces.

In all cases the compliant surfaces may be implemented by means of various passive or active methods. Some possibilities for passive methods include, but are not limited to, low friction pads, rollers, or bearings supported by springs or other mechanisms. Possibilities for active methods include, but are not limited to, electromechanical, pneumatic, hydraulic, piezoelectric or other active adaptive means. As the cartridge gets further into the slot of the universal media module, it eventually leaves the guides of the previous location and must now be completely supported by the universal media module. If the two slot locations' support zones are spaced a distance apart, the cartridge must be constrained from the top side as well. This is accomplished by compliant mechanisms which prevent the cartridge's rotation due to gravity or inertial acceleration before the cartridge's center of gravity is inside of the universal media module's bottom support.

In the case of the smaller varieties of objects or data storage media cartridges the compliant controlling surfaces are operated at or near their minimum displacements. In the case of larger cartridges the control surfaces can be operated at any of the continuously variable intervals within their displacement ranges.

### BRIEF DESCRIPTION OF THE DRAWINGS

FIG. 1 is a front perspective view of the universal media module of the present invention;

FIG. 2 is a perspective view of the universal media module of the present invention removably attached to a data storage library L;

FIG. 3 is a front elevational view of the universal media module of the present invention, containing a large number of small storage slots;

FIG. 4 is a front elevational view of the universal media module of the present invention, containing a moderate number of medium storage slots;

FIG. 5 is a front elevational view of the universal media module of the present invention, containing a small number of large storage slots;

FIG. 6 is a perspective view of an LTO™ tape cartridge for use with the present invention.

FIG. 7 is a perspective view of a DLT™ tape cartridge for use with the present invention.

FIGS. 8-10 are various views of the universal media module of the present invention, illustrating the cartridge identification feature in the neutral position, before an incoming LTO cartridge engages the feature;

FIGS. 11-12 are various views of the universal media module of the present invention, illustrating the cartridge identification feature as an incoming LTO cartridge begins to engage the feature;

FIGS. 13-14 are various views of the universal media module of the present invention, illustrating the cartridge identification feature as an incoming LTO cartridge is fully engaged with the feature;

FIGS. 15-16 are various views of the universal media module of the present invention, illustrating the cartridge identification feature in the neutral position, before an incoming DLT cartridge engages the feature;

FIG. 17 is a perspective view of the universal media module of the present invention showing the cartridge identification feature pre-set to the DLT position, and a DLT cartridge entering a storage slot.

FIG. 18 is a perspective view of the universal media module of the present invention, with some external structure cut away, showing a DLT cartridge fully inserted into a storage slot.

FIG. 19 is a side elevational view of the universal media module of the present invention, showing the cartridge identification apparatus set to the LTO position and a DLT cartridge approaching the slot.

FIG. 20 is a perspective view of the universal media module of the present invention, illustrating the cartridge identification apparatus in the neutral position as an incoming DLT cartridge begins to engage the feature;

FIGS. 21-23 are various views of the universal media module of the present invention, illustrating the cartridge identification apparatus as an incoming DLT cartridge is fully engaged with the feature;

FIGS. 24-27 are perspective views showing the operation of the integral automatic cartridge retention feature of the present invention; and

FIGS. 28-29 are various views showing the operation of the adaptive part selector feature of the present invention.

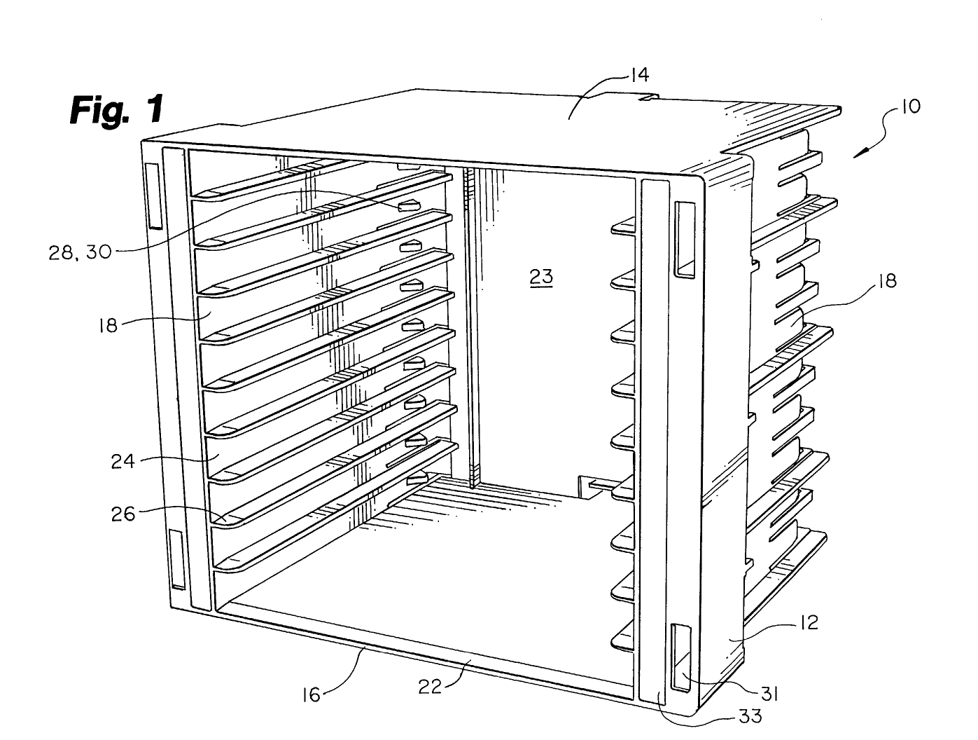

### DETAILED DESCRIPTION OF THE PREFERRED EMBODIMENT

The universal media module of the present invention is generally shown in the figures as reference numeral 10.

The universal media module 10 comprises a housing 12 having a top wall 14, bottom wall 16, and side walls 18. The module 10 also has a rear wall 20 and an open front 22.

Attached to or configured into the side walls 18 is at least one media storage slot 24. Each storage slot 24 is formed by supporting members such as a support, shelf, or rail 26 extending along each side wall 18 from the open front 22 to the rear wall 20. Associated with each storage slot 24 is a detent 28, which preferably is a spring finger 30. The detent will hold cartridges of a size specific to the storage slot, but is distinct from the adaptive part selector apparatus, discussed below, which adapts a fixed size slot to cartridges of varying size.

Preferably, the top wall 14, bottom wall 16, side walls 18, and rear wall 20 are integrally molded into a single, unitary structure.

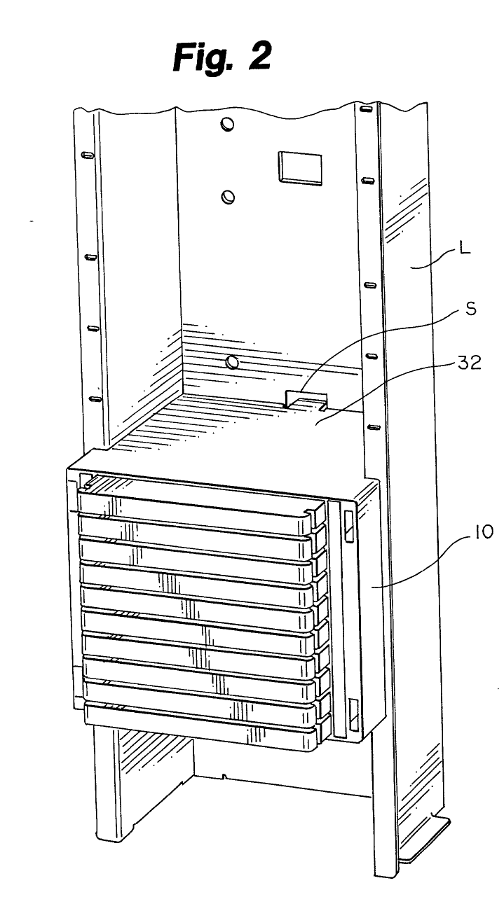

As can be seen in FIG. 2, the module 10 may be removably attached to a data storage library L by appropriate attachment means such as tabs 32 matching slots S of the storage library L.

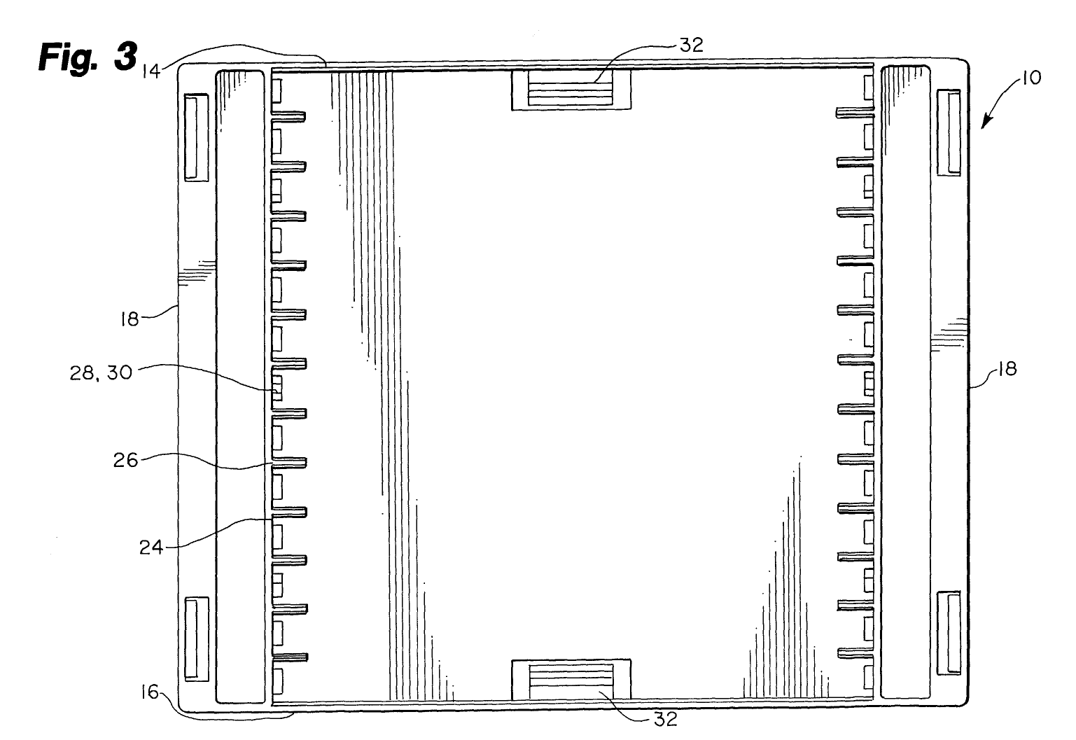

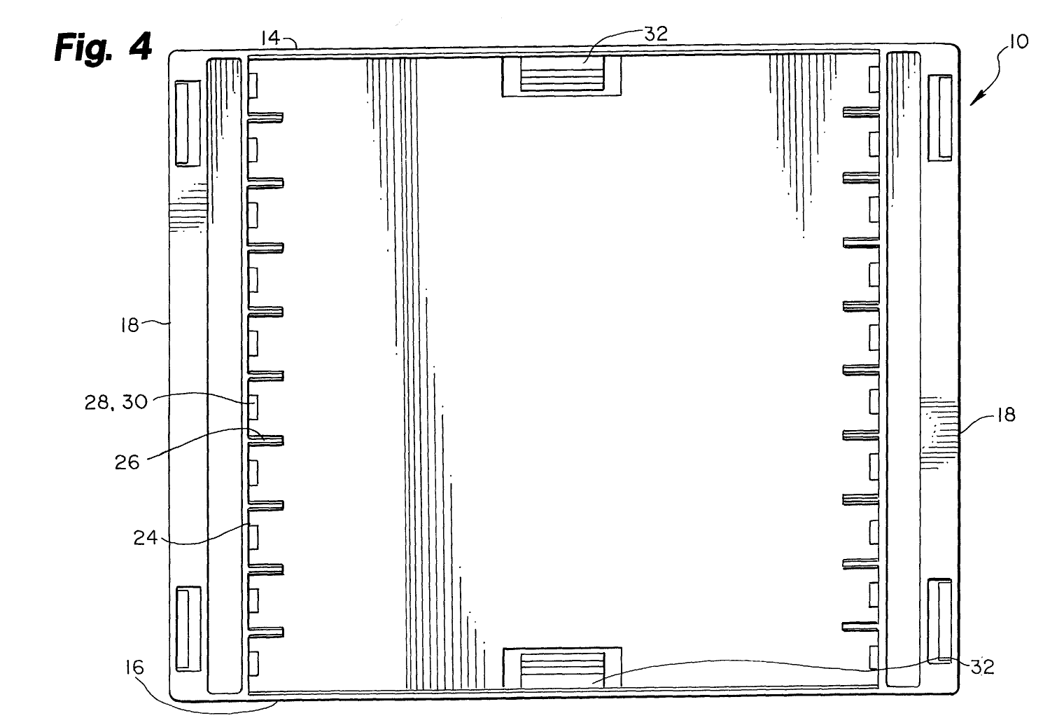

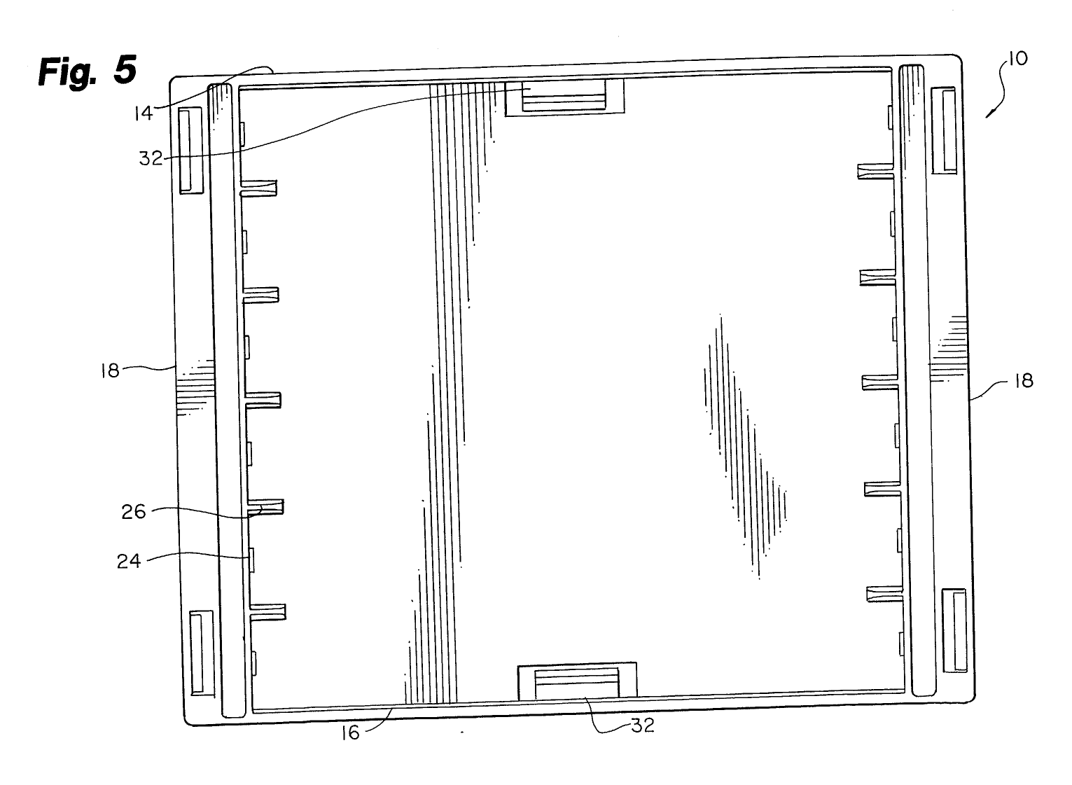

Comparing FIGS. 3, 4, and 5, it will be seen that the size and number of the storage slots 24 within the module 10 may vary. The module 10 may have a large number of small slots (FIG. 3), a moderate number of medium slots (FIG. 4), or a small number of large slots (FIG. 5).

The universal media module 10 may also include physical calibration features adapted to be sensed by the data storage library system for alignment of the data storage library alignment offsets. The physical calibration features are preferably cut-outs 31 in the housing 12.

The universal media module 10 may also include recessed molded-in areas 33 adapted for the application of slot identification labels.

### Cartridge Identification Apparatus

In one aspect, the present invention includes a cartridge identification apparatus 40 adapted to engage the identification feature of a media cartridge and to identify the media cartridge type to the operator. The media cartridge identification apparatus is associated with one or more of the storage slots 24.

The incoming cartridge has some feature F that specifically identifies the cartridge type. The cartridge identification feature 40 may be designed to recognize a variety of differing features F.

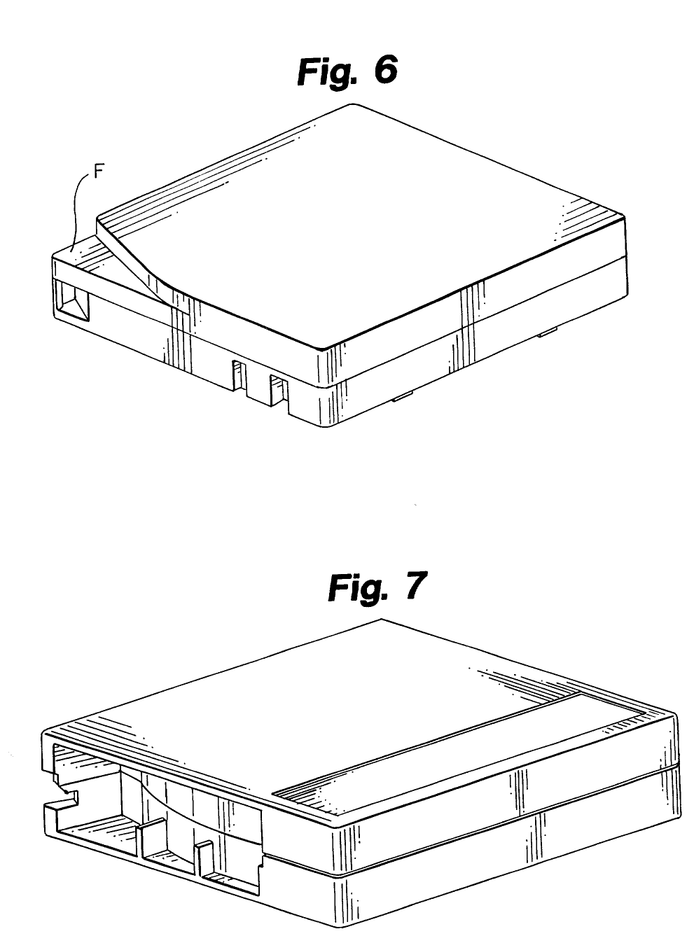

FIG. 6 is a perspective view of an LTO™ media cartridge showing a cartridge identification feature F, a shelf which will interact with the cartridge identification apparatus 40.

FIG. 7 is a perspective view of a DLT™ media cartridge with an identification feature F, a slot which will interact with the cartridge identification apparatus 40.

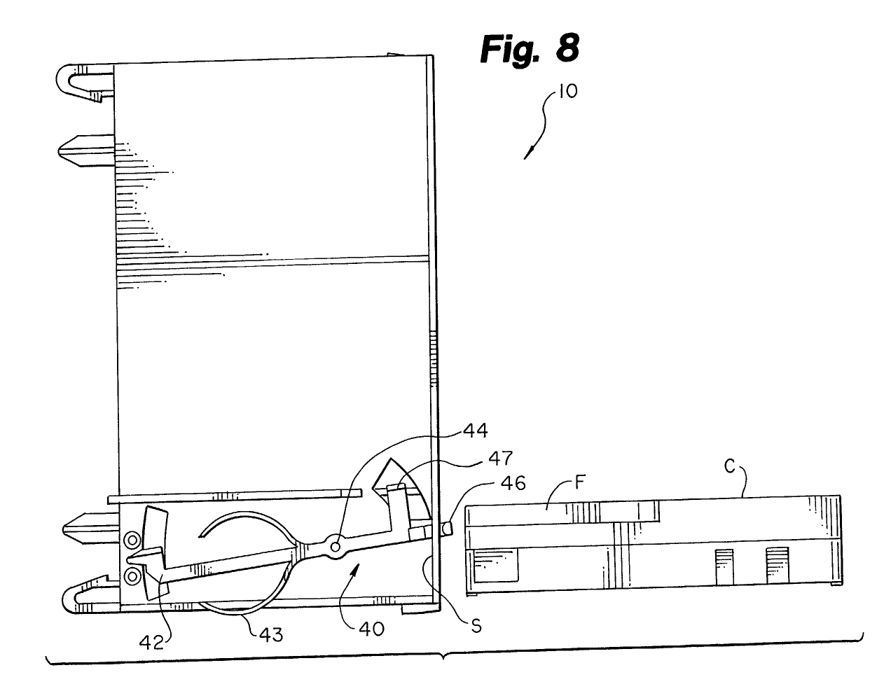

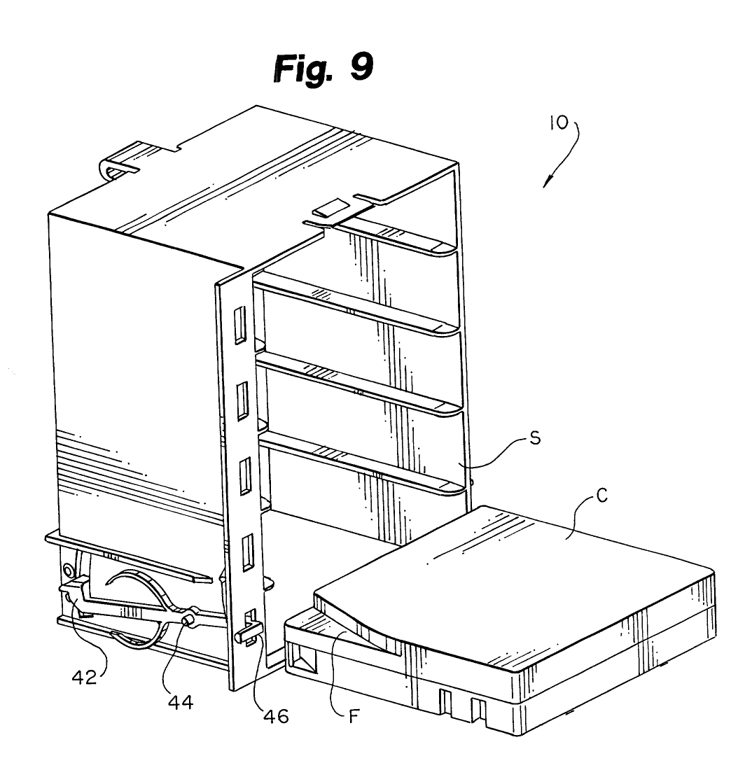

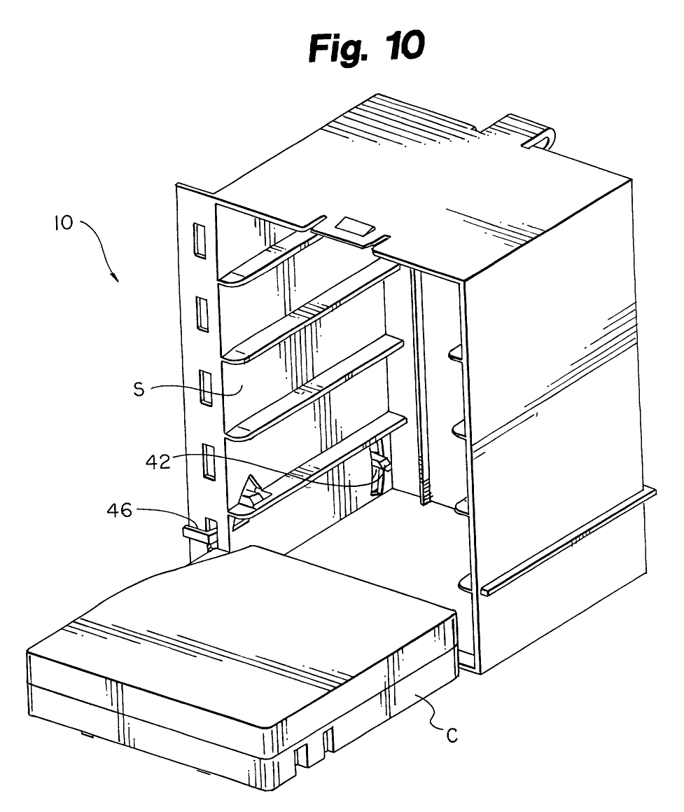

FIGS. 8-14 illustrate the operation of the cartridge identification feature 40 with LTO™ tape media.

FIGS. 8-10 show the cartridge approaching one of several storage slots S of the universal media module 10. Each of the storage slots S may be configured with the cartridge identification feature, but only one slot is shown with the feature for the purposes of explanation. In FIGS. 8-10, the cartridge identification apparatus 40 is pre-set to a neutral operational position that will accept either LTO™ or DLT™ cartridges. However, the cartridge identification feature may also be pre-set to positions that allow insertion of only an LTO™ cartridge or a DLT™ cartridge.

The cartridge identification feature 40 comprises a cartridge-keying tab 42 which engages the feature F of the incoming cartridge C. Associated with the cartridge-keying tab 42 is a media reference lever 44 that sets the storage slot S for the particular incoming media. The media reference lever 44 may preferably have a selector portion 46 that will indicate to the human operator and to the data storage library the type of media that is in a particular slot. The cartridge identification feature may have an internal biasing means such as a spring 43 that assists in locking the media reference lever into a selected position.

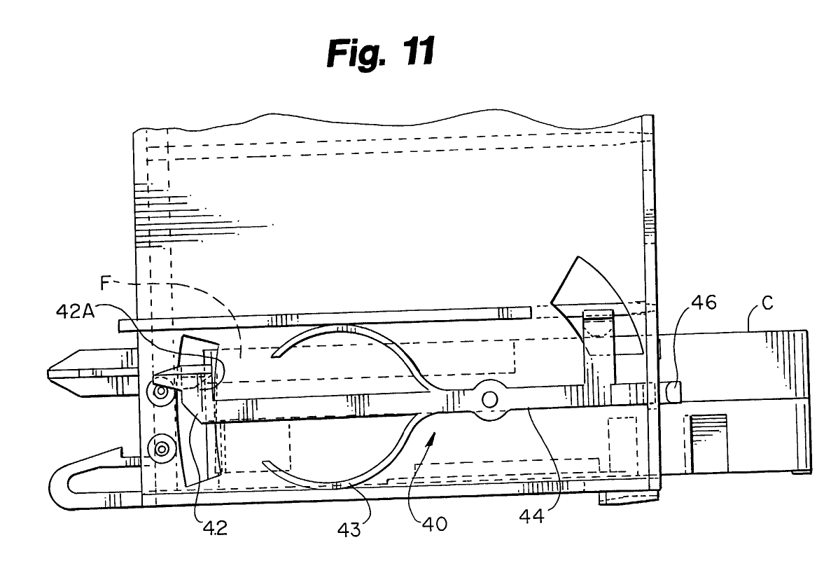

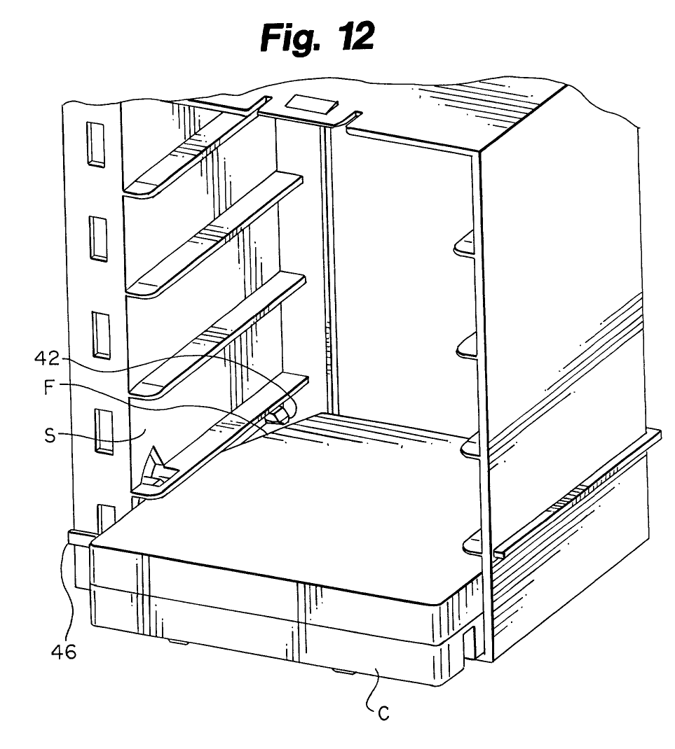

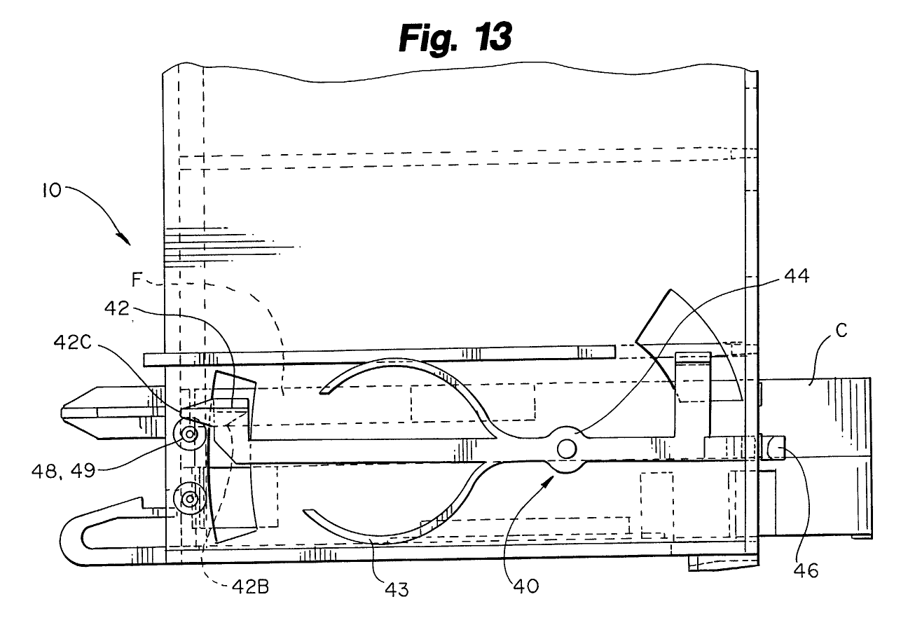

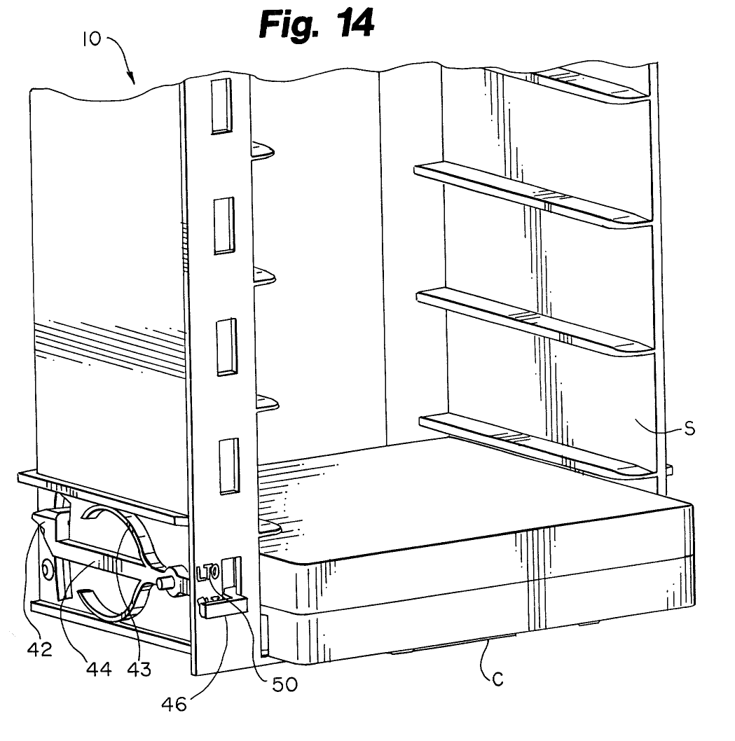

FIGS. 11-14 show the operation of the cartridge identification feature 40 as a LTO™ tape media contacts the feature 40. In FIG. 11, it will be seen that the feature F of the cartridge C has engaged the cartridge-keying tab 42 at camming surface 42A, causing the media reference lever to pivot. FIG. 12 shows the cartridge partially engaged with the identification feature 40. FIG. 13 shows that the cartridge, as it continues to be inserted into the storage slot, makes contact with camming surface 42B, causing camming surface 42C to engage a detent 48 which locks the identification apparatus 40 into the “LTO” position. The detent 48 may be a roller 49, as shown, or other equivalent detaining feature. It will also be seen (FIG. 14) that the selector portion 46 has now revealed an indicator 50 that indicates visually to the human operator that an LTO™ tape media cartridge is now in the slot.

It should also be understood that the human operator may set the cartridge reference lever to the LTO™ tape media position manually, as by grasping the selector portion 46. When the cartridge reference lever is preset to the LTO™ position, a DLT™ cartridge cannot be inserted fully into the slot S, because the cartridge keying tab 42 will abut against the cartridge.

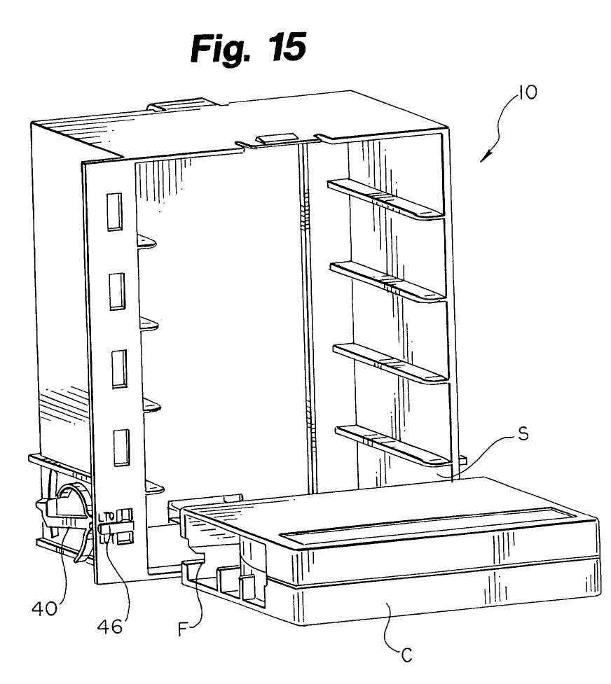

FIGS. 15-22 show the operation of the cartridge identification feature with DLT™ tape media. The identification feature of the DLT tape media is the feature F indicated in FIG. 7, a slot.

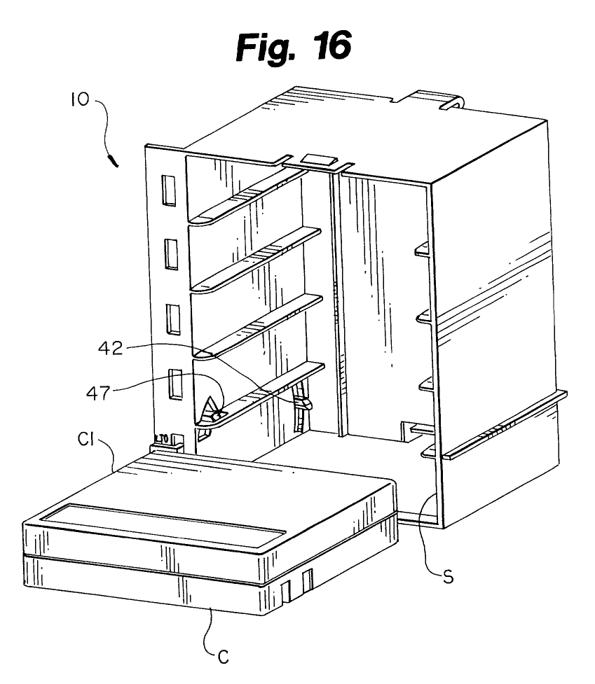

FIG. 15 shows the cartridge identification apparatus 40 pre-set to the neutral position, as can be seen by the fact that the selector portion 46 is between the “LTO” and “DLT” positions. A DLT™ cartridge C is shown approaching the slot S. FIG. 16 shows another view of this situation, and it can be seen that the cartridge keying tab 42 is in the neutral position as shown.

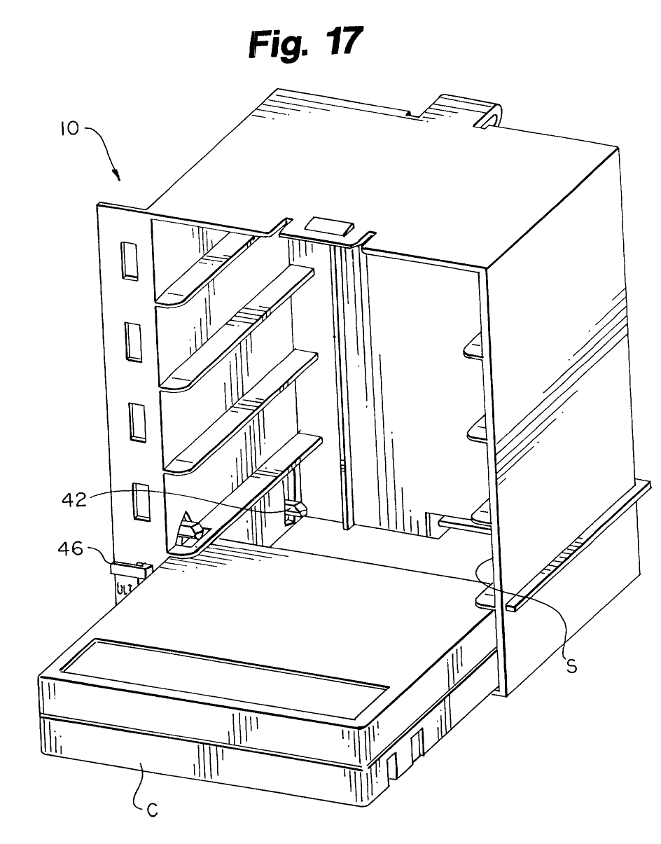

FIG. 17 shows a DLT™ cartridge C being inserted into a slot S that has been pre-set to the “DLT” position, as shown by the selector portion 46. The cartridge keying tab 42 is in the “DLT” position, where it will accept a DLT™ cartridge but not an LTO™ cartridge, because the LTO™ cartridge does not have the required slot to match with this position of the cartridge keying tab 42.

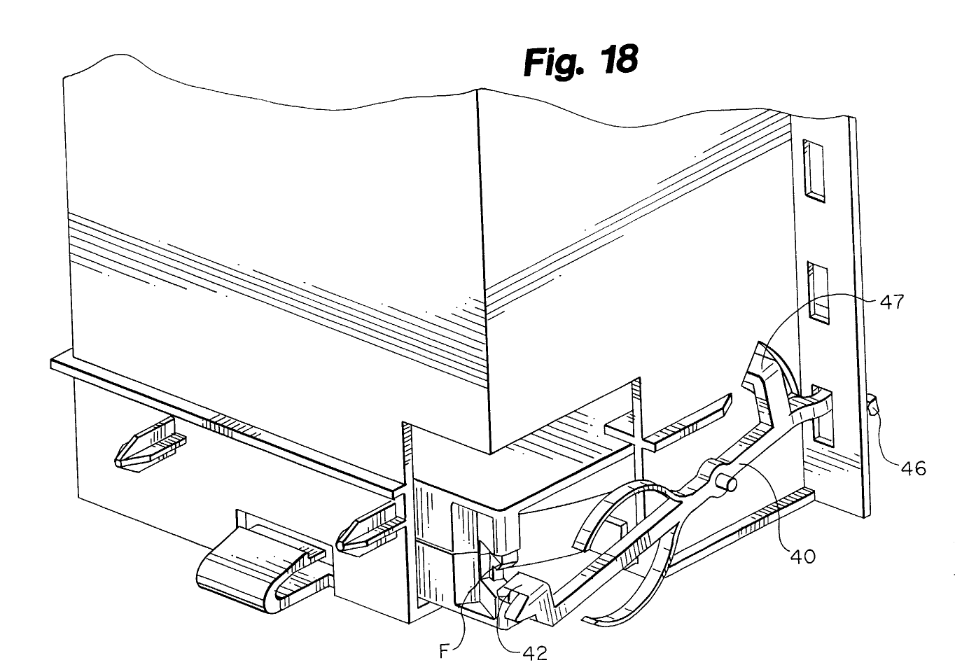

FIG. 18 shows a DLT™ cartridge C fully inserted into a slot S, with the identification feature F engaging the cartridge keying tab 42.

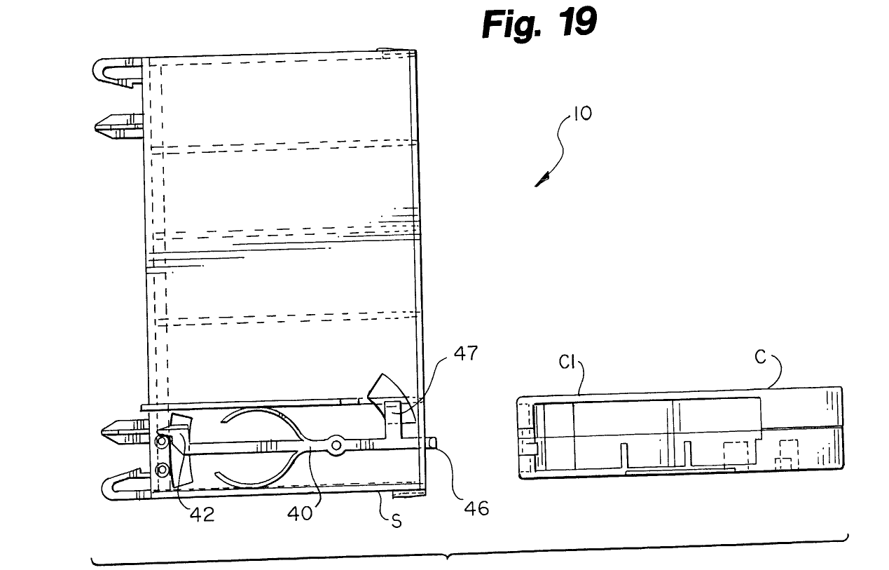

FIG. 19 is a side elevational view of a DLT™ cartridge approaching a slot S with the cartridge identification apparatus 40 in the “LTO” position. In this position, the DLT™ cartridge will be rejected because the cartridge keying tab 42 will abut against the cartridge. In contrast, when the cartridge identification apparatus is in the neutral position (FIG. 16), secondary cartridge keying tab 47 is in a position to be contacted by the top C1 of the incoming cartridge C. An incoming LTO™ cartridge (FIG. 8) would not contact the tab 47 because of the shelf F in the LTO™ cartridge shown in FIG. 6, and because the LTO™ cartridge is not as thick as the DLT™ cartridge.

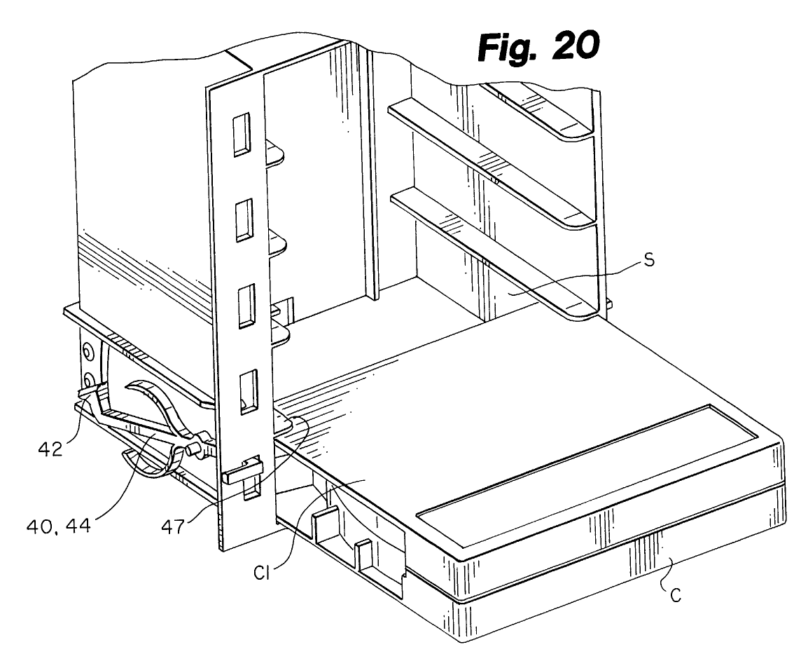

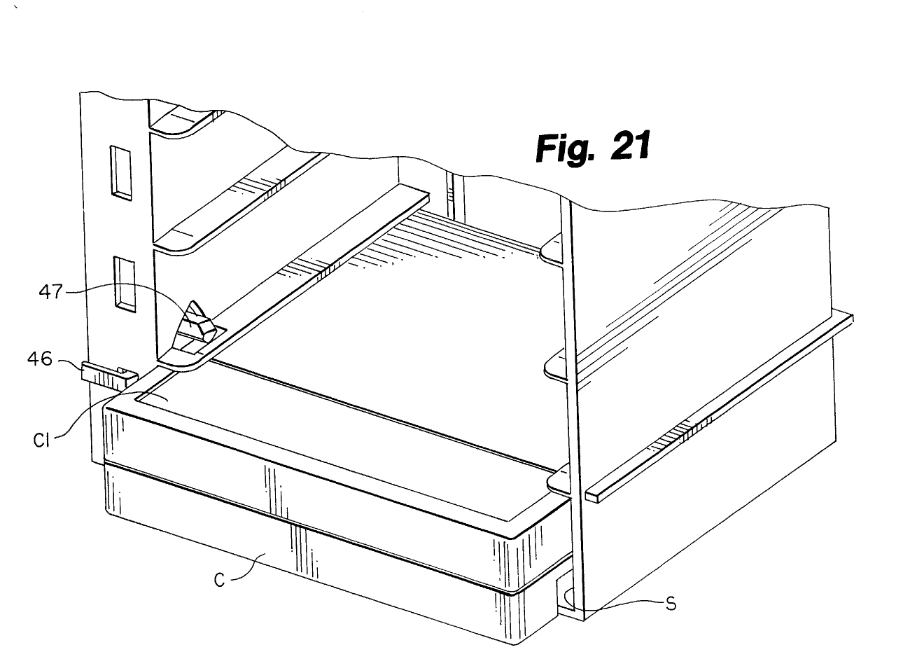

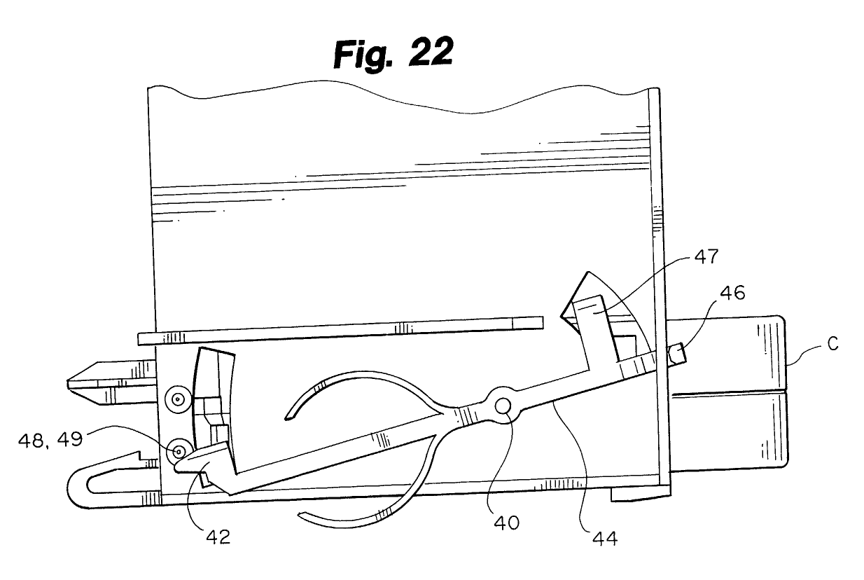

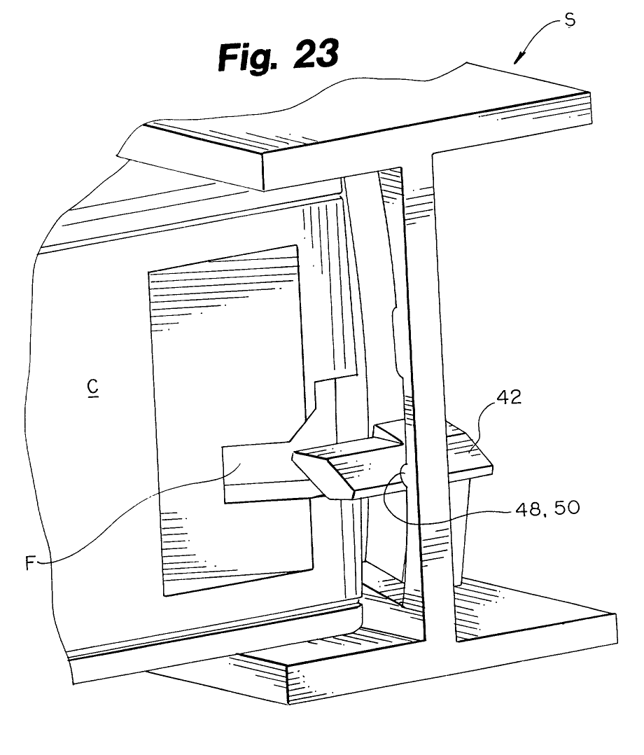

In FIG. 20 the incoming DLT™ cartridge's top C1 has contacted the secondary cartridge keying tab 47, causing the media reference lever 44 to pivot and causing the cartridge keying tab 42 to be forced downwardly into a position in which it will accept the identification feature F of the DLT™ cartridge. In FIG. 21, the cartridge C has been fully inserted in the slot S. FIG. 22 shows a side elevational view of the module 10, with the cartridge keying tab 42 engaging the detent 48 (roller 49), locking the identification apparatus 40 into the “DLT” position. FIG. 23 shows a rear perspective view of the slot S, with the cartridge keying tab 42 clearing the feature F of the cartridge C, and the cartridge keying tab 42 engaging a detent 48, which in another embodiment is a raised area 50 rather than a roller 49.

### Integral Automatic Retention Feature

In another aspect, the invention includes an automatic cartridge retention feature adapted to engage the cartridge retaining feature when the universal media module is removed from the storage array and disengage from the cartridge retention feature when the universal media module is inserted into the storage array. The retention feature thus holds the cartridge securely in the slot when the universal media module is removed from the storage array, yet releases the cartridge when the universal media module is inserted into the storage array, allowing the cartridge to be picked by library robotics.

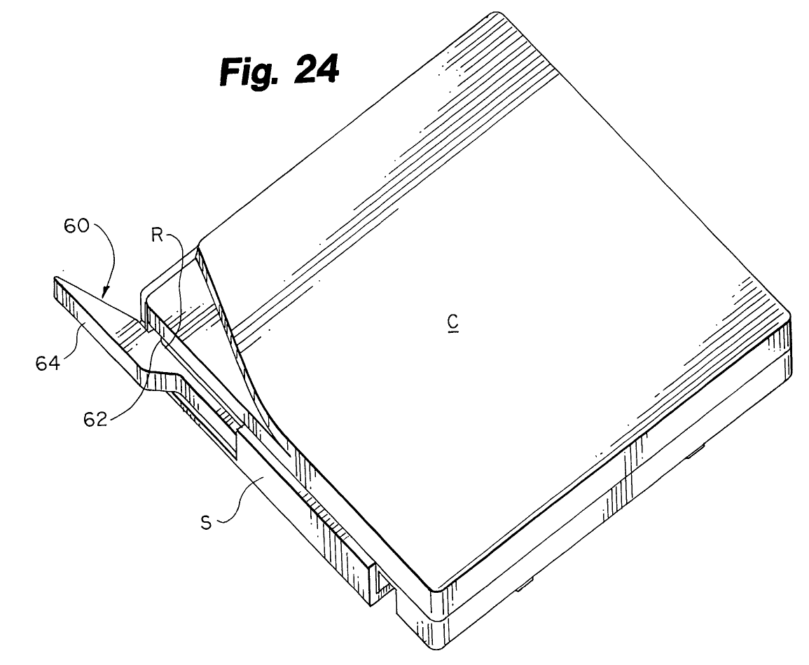

FIGS. 24-27 show the operation of the automatic cartridge retention feature.

FIG. 24 shows a slot S of the universal media module 10 containing an inserted cartridge C. The cartridge C has a retaining feature R, such as a cutout which cooperates with the automatic cartridge retention feature 60.

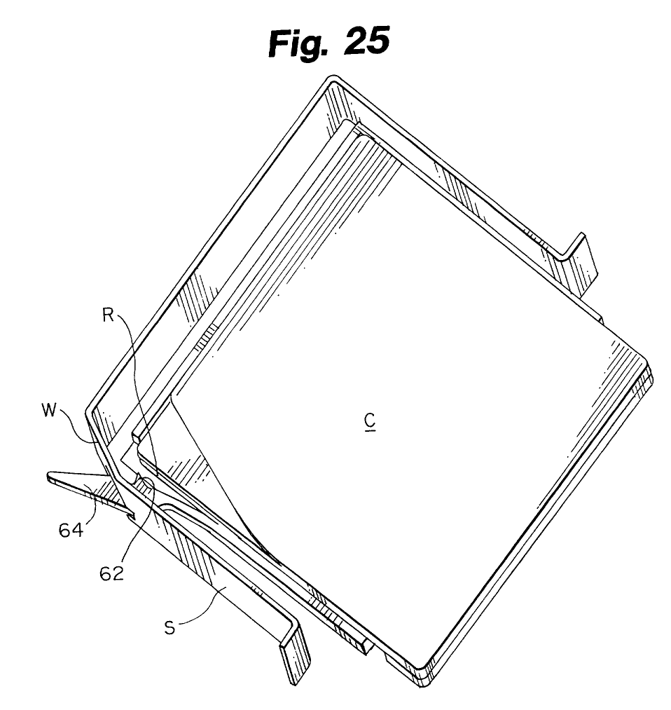

The automatic cartridge retention feature 60 comprises a retention member 62 which engages the cartridge retaining feature R when the universal media module 10 is not in contact with the cartridge store walls. As shown in FIG. 25, the automatic cartridge retention feature 60 also includes a disengagement member 64 which engages the walls W of the cartridge store when the universal media module 10 is inserted into the cartridge store. This engagement of the disengagement member 64 with the walls W causes the disengagement member 64 to deflect the retention member 62 from the cartridge retaining feature R, thus allowing the cartridge to be removed from the slot S by the data storage library robotics.

Removal of the universal media module 10 from the cartridge store allows the retention member 62 to relax to its free state so that it engages the cartridge C, preventing it from dislodging.

The cartridge retention feature 60 relies on a positive engagement of the cartridge without friction or applied load, to help retain the cartridge in the magazine upon removal from the library. In the library, the retention member 62 is pried open by the media storewall, reducing the total detent force allowing the cartridge to be removed with ease.

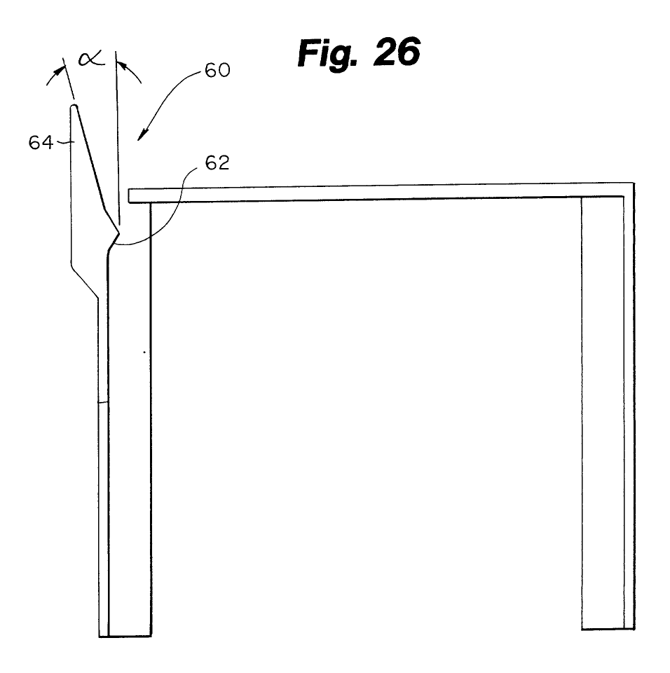

Two embodiments of the cartridge retention feature 60 are shown. The first embodiment, illustrated in FIG. 26, allows the cartridge C to overcome the load from the retention feature when the universal media module is removed from the cartridge store. This is accomplished by having an angle α between the cartridge C and the retention member 62 of about 45°. Since the angle α, being sloped with respect to the cartridge notch surface, is much less than 90°, the cartridge can overcome the load from the retention feature.

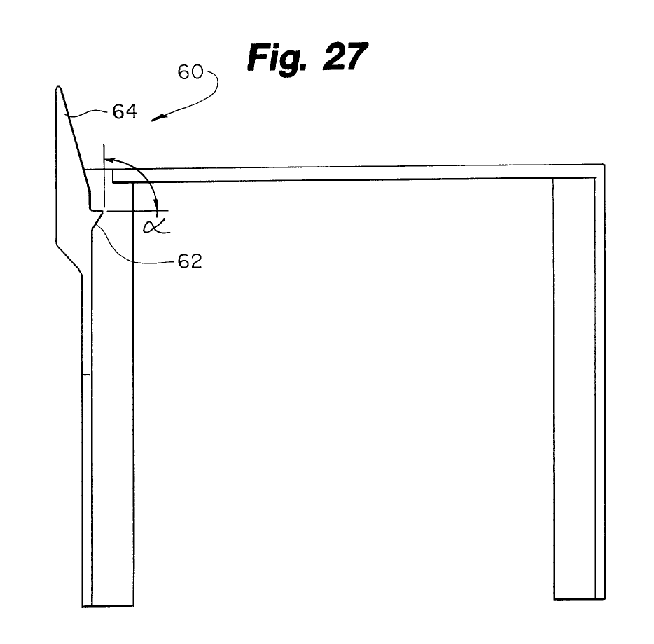

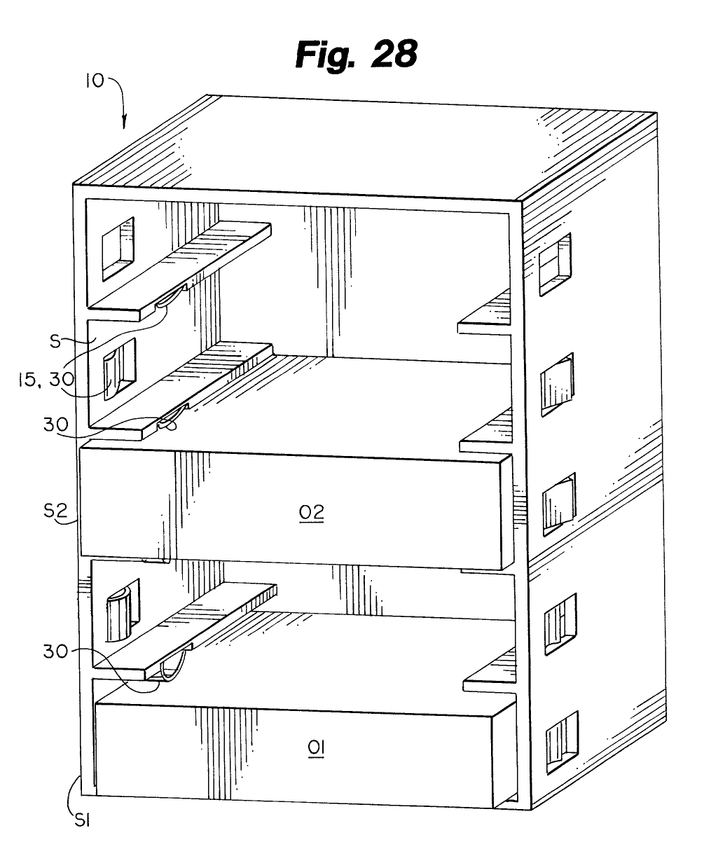

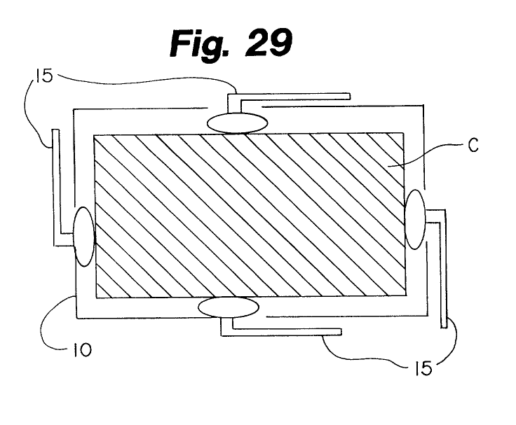

A second embodiment of the retention feature 60 is shown in FIG. 27. Here, the angle α between the cartridge and the retention member 62 is about 90°. The cartridge cannot overcome the load from the retention feature as there is no component of the cartridge pulling force that would act in the direction required to deflect the retention member.

### Adaptive Part Selector

In another aspect, the present invention includes an adaptive part selector apparatus to adapt a given module slot to cartridges of varying sizes, yet holding the various size cartridges within the slot. The adaptive part selector apparatus is adapted to contact media cartridges varying in at least one dimension and is deflectable along that dimension in response to the insertion of a media cartridge into a slot.

Various embodiments of the adaptive part selector feature of the present invention may be used. In all aspects of the invention, a compliant member 15 may be used to guide and hold the media within the universal media module.

In one embodiment, shown in FIG. 26, a leaf spring 30 projects into the slot S. Object O1, when inserted into slot S1, is of relatively small thickness and thus deflects the leaf spring 30 only slightly. However, object O2, inserted into slot S2, is thicker than object O1 and deflects the leaf spring 30 further.

Other embodiments of the adaptive part selector apparatus are disclosed in U.S. patent application Ser. No. 09/697,193, filed Oct. 26, 2000 and herein incorporated by reference. The adaptive part selector apparatus may thus include, additionally: a leaf spring and pad; a leaf spring and roller; a torsion spring and pad; and a torsion spring and roller.

FIG. 27 illustrates that a compliant member 15 may be used at the top, bottom, and sides of the universal media module 10.

The present invention may be embodied in other specific forms without departing from the spirit or essential attributes thereof, and it is therefore desired that the present embodiment be considered in all respects as illustrative and not restrictive.

What is claimed:

1. A universal media module for use with a data storage library system containing at least one storage array adapted to hold at least one universal media module, the universal media module being removable from the storage array, the universal media module being capable of containing a variety of media cartridges of various sizes, the media cartridges having a cartridge identification feature, the media cartridges having a retention feature, the media cartridges varying in size in at least one dimension, the universal media module comprising:
a) a housing having a top wall, bottom wall, side walls, rear wall, and an open front;
b) means for removably attaching the housing to the data storage library system; and
c) at least one media storage slot formed by supporting members engaging the side walls of the housing and extending along the side walls from the open front to the rear wall, the at least one media storage slot further comprising a detent adapted to engage a media cartridge;
wherein the number and size of the media storage slots between the top wall and bottom wall is variable.

2. The universal media module of claim 1, wherein the top wall, bottom wall, side walls, rear wall, and supporting members are integrally molded.

3. The universal media module of claim 1, further comprising physical calibration features adapted to be sensed by the data storage library system for alignment of the data storage library alignment offsets.

4. The universal media module of claim 3, wherein the physical calibration features further comprise cut-outs in the housing.

5. The universal media module of claim 1, further comprising recessed molded-in areas adapted for the application of slot identification labels.

6. The universal media module of claim 1, the at least one media storage slot further comprising a media cartridge identification apparatus adapted to engage the identification feature of a media cartridge and to identify the media cartridge type to the operator.

7. The universal media module of claim 6, wherein the media cartridge identification apparatus has a neutral position allowing more than one type of media cartridge to be inserted into the media storage slot and wherein the media cartridge identification apparatus has at least one pre-set position that allows insertion of only one type of media cartridge into the media storage slot.

8. The universal media module of claim 1, wherein the at least one media storage slot further comprises an automatic media cartridge retention apparatus adapted to disengage the media cartridge retention feature when the media storage module is attached to the data storage library system and adapted to engage the media cartridge retention feature when the media storage module is removed from the data storage library system.

9. The universal media module of claim 1, the at least one media storage slot further comprising an adaptive part selector apparatus adapted to contact the media cartridge and being deflectable along at least one dimension to securely hold a media cartridge within the at least one media storage slot.

10. A universal media module for use with a data storage library system containing at least one storage array adapted to hold at least one universal media module, the universal media module being removable from the storage array, the universal media module being capable of containing a variety of media cartridges of various sizes, the media cartridges having an identification feature, the universal media module comprising:
a) a housing having a top wall, bottom wall, side walls, rear wall, and an open front;
b) means for removably attaching the housing to the data storage library system; and
c) at least one media storage slot formed by supporting members engaging the side walls of the housing and extending along the side walls from the open front to the rear wall, the at least one media storage slot further comprising a detent adapted to engage a media cartridge;
d) the at least one media storage slot further comprising a media cartridge identification apparatus adapted to engage the identification feature of a media cartridge and to identify the media cartridge type to the operator.

11. The universal media module of claim 10, wherein the top wall, bottom wall, side walls, rear wall, and supporting members are integrally molded.

12. The universal media module of claim 10, further comprising physical calibration features adapted to be sensed by the data storage library system for alignment of the data storage library alignment offsets.

13. The universal media module of claim 12, wherein the physical calibration features further comprise cut-outs in the housing.

14. The universal media module of claim 10, further comprising recessed molded-in areas adapted for the application of slot identification labels.

15. The universal media module of claim 10, wherein the media cartridge identification apparatus has a neutral position allowing more than one type of media cartridge to be inserted into the media storage slot and wherein the media cartridge identification apparatus has at least one pre-set position that allows insertion of only one type of media cartridge into the media storage slot.

16. The universal media module of claim 10, wherein the at least one media storage slot further comprises an automatic media cartridge retention apparatus adapted to disengage the media cartridge retention feature when the media storage module is attached to the data storage library system and adapted to engage the media cartridge retention feature when the media storage module is removed from the data storage library system.

17. The universal media module of claim 16, wherein the automatic media cartridge retention apparatus is integrally molded with the housing.

18. The universal media module of claim 10, the at least one media storage slot further comprising an adaptive part selector apparatus adapted to contact the media cartridge and being deflectable along at least one dimension to securely hold a media cartridge within the at least one media storage slot.

19. The universal media module of claim 10, wherein the media cartridge identification apparatus further comprises a pivoting media reference lever, a cartridge-keying tab adapted to engage the cartridge identification feature and attached to one end of the media reference lever, a selection indicator portion attached to the second end of the media reference lever, and a spring adapted to lock the media reference lever into a position wherein the media storage slot will only accept media cartridges of a single type.

20. A universal media module for use with a data storage library system containing at least one storage array adapted to hold at least one universal media module, the universal media module being removable from the storage array, the universal media module being capable of containing a variety of media cartridges of various sizes, the media cartridges having a retention feature, the universal media module comprising:
a) a housing having a top wall, bottom wall, side walls, rear wall, and an open front;
b) means for removably attaching the housing to the data storage library system; and
c) at least one media storage slot formed by supporting members engaging the side walls of the housing and extending along the side walls from the open front to the rear wall, the at least one media storage slot further comprising a detent adapted to engage a media cartridge;
d) wherein the at least one media storage slot further comprises an automatic media cartridge retention apparatus adapted to disengage the media cartridge retention feature when the media storage module is attached to the data storage library system and adapted to engage the media cartridge retention feature when the media storage module is removed from the data storage library system.

21. The universal media module of claim 20, wherein the top wall, bottom wall, side walls, rear wall, and supporting members are integrally molded.

22. The universal media module of claim 20, further comprising physical calibration features adapted to be sensed by the data storage library system for alignment of the data storage library alignment offsets.

23. The universal media module of claim 22, wherein the physical calibration features further comprise cut-outs in the housing.

24. The universal media module of claim 20, further comprising recessed molded-in areas adapted for the application of slot identification labels.

25. The universal media module of claim 20, the at least one media storage slot further comprising a media cartridge identification apparatus adapted to engage the identification feature of a media cartridge and to identify the media cartridge type to the operator.

26. The universal media module of claim 25, wherein the media cartridge identification apparatus has a neutral position allowing more than one type of media cartridge to be inserted into the media storage slot and wherein the media cartridge identification apparatus has at least one pre-set position that allows insertion of only one type of media cartridge into the media storage slot.

27. The universal media module of claim 20, wherein the automatic media cartridge retention apparatus is integrally molded with the housing.

28. The universal media module of claim 20, the at least one media storage slot further comprising an adaptive part selector apparatus adapted to contact the media cartridge and being deflectable along at least one dimension to securely hold a media cartridge within the at least one media storage slot.

29. The universal media module of claim 20, wherein the automatic media cartridge retention apparatus further comprises a retention member adapted to engage the cartridge retaining feature when the universal media module is removed from the storage array and a disengagement member adapted to engage the storage array and to deflect the retention member away from the cartridge retaining feature when the universal media module is inserted into the storage array.

30. The universal media module of claim 29, having an angle between the retention member and the cartridge of about 45°.

31. The universal medial module of claim 29, having an angle between the retention member and the cartridge of about 90°.

32. A universal media module for use with a data storage library system containing at least one storage array adapted to hold at least one universal media module, the universal media module being removable from the storage array, the universal media module being capable of containing a variety of media cartridges of various sizes, the media cartridges varying in size in at least one dimension, the universal media module comprising:
a) a housing having a top wall, bottom wall, side walls, rear wall, and an open front;
b) means for removably attaching the housing to the data storage library system;
c) at least one media storage slot formed by supporting members engaging the side walls of the housing and extending along the side walls from the open front to the rear wall, the at least one media storage slot further comprising a detent adapted to engage a media cartridge; and
d) the at least one media storage slot further comprising an adaptive part selector apparatus adapted to contact media cartridges of varying size and being deflectable along at least one dimension to securely hold media cartridges varying in size in that dimension within the at least one media storage slot.

33. The universal media module of claim 32, wherein the top wall, bottom wall, side walls, rear wall, and supporting members are integrally molded.

34. The universal media module of claim 32, further comprising physical calibration features adapted to be sensed by the data storage library system for alignment of the data storage library alignment offsets.

35. The universal media module of claim 34, wherein the physical calibration features further comprise cut-outs in the housing.

36. The universal media module of claim 32, further comprising recessed molded-in areas adapted for the application of slot identification labels.

37. The universal media module of claim 32, the at least one media storage slot further comprising a media cartridge identification apparatus adapted to engage the identification feature of a media cartridge and to identify the media cartridge type to the operator.

38. The universal media module of claim 37, wherein the media cartridge identification apparatus has a neutral position allowing more than one type of media cartridge to be inserted into the media storage slot and wherein the media cartridge identification apparatus has at least one pre-set position that allows insertion of only one type of media cartridge into the media storage slot.

39. The universal media module of claim 32, wherein the at least one media storage slot further comprises an automatic media cartridge retention apparatus adapted to disengage the media cartridge retention feature when the media storage module is attached to the data storage library system and adapted to engage the media cartridge retention feature when the media storage module is removed from the data storage library system.

40. The universal media module of claim 39, wherein the automatic media cartridge retention apparatus is integrally molded with the housing.

41. The universal media module of claim 32, wherein the adaptive part selector apparatus further comprises passive positioning mechanisms selected from the group consisting of: a leaf spring; a leaf spring and pad; a leaf spring and roller; a torsion spring and pad; and a torsion spring and roller.

42. A universal media module for use with a data storage library system containing at least one storage array adapted to hold at least one universal media module, the universal media module being removable from the storage array, the universal media module being capable of containing a variety of media cartridges of various sizes, the media cartridges varying in size in at least one dimension, the media cartridges having an identification feature, the media cartridges having a retention feature, the universal media module comprising:
a) a housing having a top wall, bottom wall, side walls, rear wall, and an open front;
b) means for removably attaching the housing to the data storage library system;
c) at least one media storage slot formed by supporting members engaging the side walls of the housing and extending along the side walls from the open front to the rear wall;
d) the at least one media storage slot further comprising features selected from the group consisting of: an adaptive part selector apparatus adapted to contact media cartridges of varying size and being deflectable along at least one dimension to securely hold media cartridges varying in size in that dimension within the at least one media storage slot; a media cartridge identification apparatus adapted to engage the identification feature of a media cartridge and to identify the media cartridge type to the operator; and an automatic media cartridge retention apparatus adapted to disengage the media cartridge retention feature when the media storage module is attached to the data storage library system and adapted to engage the media cartridge retention feature when the media storage module is removed from the data storage library system.

43. The universal media module of claim 42, wherein the top wall, bottom wall, side walls, rear wall, and supporting members are integrally molded.

44. The universal media module of claim 42, further comprising physical calibration features adapted to be sensed by the data storage library system for alignment of the data storage library alignment offsets.

45. The universal media module of claim 44, wherein the physical calibration features further comprise cut-outs in the housing.

46. The universal media module of claim 42, further comprising recessed molded-in areas adapted for the application of slot identification labels.

47. The universal media module of claim 42, wherein the media cartridge identification apparatus has a neutral position allowing more than one type of media cartridge to be inserted into the media storage slot and wherein the media cartridge identification apparatus has at least one pre-set position that allows insertion of only one type of media cartridge into the media storage slot.

48. The universal media module of claim 42, wherein the automatic media cartridge retention apparatus is integrally molded with the housing.

49. The universal media module of claim 42, wherein the adaptive part selector apparatus further comprises passive positioning mechanisms selected from the group consisting of: a leaf spring and pad; a leaf spring and roller; a torsion spring and pad; and a torsion spring and roller.

50. The universal media module of claim 42, wherein the number and size of the media storage slots between the top wall and bottom wall is variable.

51. The universal media module of claim 42, the at least one media storage slot further comprising a detent adapted to engage a media cartridge.

52. A universal media module for use with a data storage library system containing at least one storage array adapted to hold at least one universal media module, the universal media module being removable from the storage array, the universal media module being capable of containing a variety of media cartridges of various sizes, the media cartridges varying in size in at least one dimension, the media cartridges having an identification feature, the media cartridges having a retention feature, the universal media module comprising:
a) a housing having a top wall, bottom wall, side walls, rear wall, and an open front;
b) means for removably attaching the housing to the data storage library system;
c) at least one media storage slot formed by supporting members engaging the side walls of the housing and extending along the side walls from the open front to the rear wall, the at least one media storage slot further comprising a detent adapted to engage a media cartridge;
d) the at least one media storage slot further comprising an adaptive part selector apparatus adapted to contact media cartridges of varying size and being deflectable along at least one dimension to securely hold media cartridges varying in that dimension within the at least one media storage slot;
e) the at least one media storage slot further comprising a media cartridge identification apparatus adapted to engage the identification feature of a media cartridge and to identify the media cartridge type to the operator;
f) the at least one media storage slot further comprising an automatic media cartridge retention apparatus adapted to disengage the media cartridge retention feature when the media storage module is attached to the data storage library system and adapted to engage the media cartridge retention feature when the media storage module is removed from the data storage library system wherein the number and size of the media storage slots between the top wall and bottom wall is variable.
